(19) United States
(12) Patent Application Publication
(10) Pub. No.: US 2026/0206657 A1
(43) Pub. Date: Jul. 16, 2026

(54) SEMICONDUCTOR PACKAGE INCLUDING REDISTRIBUTION STRUCTURE

(71) Applicant: SAMSUNG ELECTRONICS CO., LTD., Suwon-si (KR)

(72) Inventors: Ikkyu Jin, Suwon-si (KR); Jinsu Kim, Suwon-si (KR); Kiju Lee, Suwon-si (KR)

(73) Assignee: SAMSUNG ELECTRONICS CO., LTD., Suwon-si (KR)

(21) Appl. No.: 19/271,226

(22) Filed: Jul. 16, 2025

(30) Foreign Application Priority Data
Jan. 14, 2025 (KR) 10-2025-0005285

(51) Int. Cl. H01L 23/498; H01L 21/48; H01L 23/00; H01L 23/31; H01L 25/16

(52) U.S. Cl. CPC H10W 90/701; H10W 70/093; H10W 70/66; H10W 72/20; H10W 74/111; H10W 90/00

(57) ABSTRACT

A semiconductor package includes a redistribution structure including a first surface and a second surface opposite to the first surface, and including an insulating layer and redistribution conductors on the insulating layer, a pillar bump on the first surface and coupled with the redistribution conductors, a solder bump on the pillar bump, a first chip structure and a second chip structure on the second surface and coupled with each other through the redistribution conductors, and a molding layer at partially covering the first chip structure and the second chip structure. The pillar bump includes an upper surface coupled with the redistribution conductors, a lower surface coupled with the solder bump, and a side surface intersecting the upper surface and the lower surface. A width of the lower surface of the pillar bump is smaller than a width of the upper surface of the pillar bump, in a first direction.

### CROSS-REFERENCE TO RELATED APPLICATIONS

This application claims priority under 35 U.S.C. § 119 to Korean Patent Application No. 10-2025-0005285, filed on Jan. 14, 2025, in the Korean Intellectual Property Office, the disclosure of which is incorporated by reference herein in its entirety.

### BACKGROUND

### 1. Field

The present disclosure relates generally to semiconductor packages, and more particularly, to semiconductor packages including a redistribution structure.

### 2. Description of Related Art

Recent advances in electronic devices that may decrease a physical form factor of the electronic devices and/or increase performance levels may also increase demand for semiconductor packages with relatively fine-pitch input/output terminals. For example, when a semiconductor package is surface-mounted on a module substrate, a main board, or the like through solder bumps, a short circuit may occur between the solder bumps arranged in response to the fine pitch of the input/output terminals, which may limit the fine-pitch design of the input/output terminals and solder bumps.

### SUMMARY

One or more example embodiments of the present disclosure provide a semiconductor package having improved reliability, when compared to related semiconductor packages.

According to an aspect of the present disclosure, a semiconductor package includes a redistribution structure including a first surface and a second surface opposite to the first surface, and including an insulating layer and redistribution conductors on the insulating layer, a pillar bump on the first surface and coupled with the redistribution conductors, a solder bump on the pillar bump, a first chip structure and a second chip structure on the second surface and coupled with each other through the redistribution conductors, and a molding layer at partially covering the first chip structure and the second chip structure. The pillar bump includes an upper surface coupled with the redistribution conductors, a lower surface coupled with the solder bump, and a side surface intersecting the upper surface and the lower surface. A second width of the lower surface of the pillar bump is smaller than a first width of the upper surface of the pillar bump, in a first direction. The side surface of the pillar bump includes a concave surface in the first direction.

According to an aspect of the present disclosure, a semiconductor package includes a redistribution structure including a first surface and a second surface opposite to the first surface, and including redistribution conductors, a pillar bump on the first surface and coupled with the redistribution conductors, a chip structure on the second surface and coupled with the redistribution conductors, and a molding layer at partially covering the chip structure. A lowermost redistribution conductor from among the redistribution conductors includes a redistribution pattern, a redistribution via coupling the redistribution pattern with the pillar bump, and a seed layer extending between the redistribution via and the pillar bump. The pillar bump includes a first metal. The seed layer includes a second metal having an etching selectivity with respect to the first metal.

According to an aspect of the present disclosure, a semiconductor package includes a redistribution structure including a first surface and a second surface opposite to the first surface, and including an insulating layer and redistribution conductors on the insulating layer, a pillar bump on the first surface and coupled with the redistribution conductors, a solder bump on the pillar bump, and at least one chip structure on the second surface and coupled with the redistribution conductors. The pillar bump includes a side surface exposed from the insulating layer. The side surface of the pillar bump includes a concave surface.

According to an aspect of the present disclosure, a method of manufacturing a semiconductor package includes preparing a carrier substrate provided with a thin film layer and a metal layer sequentially stacked thereon, forming a redistribution structure including an insulating layer on the metal layer of the carrier substrate, and redistribution conductors on the insulating layer, mounting a chip structure on the redistribution structure, forming a molding layer covering the chip structure, detaching the carrier substrate including the thin film layer from the metal layer, partially etching the metal layer and forming pillar bumps, and forming solder bumps on the pillar bumps. Each of the pillar bumps has an upper surface contacting the redistribution conductors, a lower surface contacting the solder bumps, and a side surface intersecting the upper surface and the lower surface. The lower surface of the pillar bump has a second width, smaller than a first width of the upper surface of the pillar bump, in a first direction. The side surface of the pillar bump is a concave surface in the first direction. The pillar bumps are formed using a wet etching process. The thin film layer and the metal layer include copper (Cu) or an alloy thereof. The redistribution conductors further include a seed layer in contact with the upper surface of the pillar bumps. The seed layer includes at least one of titanium (Ti), copper (Cu), or an alloy of at least one thereof.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description, taken in conjunction with the accompanying drawings, in which:

FIG. 1A is a cross-sectional view of a semiconductor package, according to an example embodiment;

FIG. 1B is a partially enlarged view of an area A of FIG. 1A, according to an example embodiment;

FIG. 1C is a cross-sectional view of line I-I′ of FIG. 1B, according to an example embodiment;

FIG. 2 is a partially enlarged view of a semiconductor package, according to an example embodiment;

FIG. 3 is a partially enlarged view of a semiconductor package, according to an example embodiment;

FIG. 4 is a partially enlarged view of a semiconductor package, according to an example embodiment;

FIGS. 5A, 5B, 5C, 5D, 5E, 5F, 5G, 5H, 5I, and 5J are diagrams illustrating a manufacturing process of a semiconductor package, according to an example embodiment;

FIG. 6 is a cross-sectional view of a semiconductor package, according to an example embodiment;

FIG. 7 is a cross-sectional view of a semiconductor package, according to an example embodiment;

FIG. 8 is a cross-sectional view of a semiconductor package, according to an example embodiment; and

FIG. 9 is a cross-sectional view of a semiconductor package, according to an example embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Hereinafter, example embodiments are described with reference to the attached drawings. Unless otherwise specifically stated, in the present disclosure, terms such as, but not limited to, “upper,” “upper surface,” “lower,” “lower surface,” “side surface,” or the like are based on the drawings and may actually vary depending on the direction in which the components are disposed.

In addition, ordinal numbers such as, but not limited to, “first,” “second,” “third,”, or the like may be used as labels for specific elements, operations, directions, or the like to distinguish various elements, operations, directions, or the like. Terms that are not described using “first,” “second,” or the like in the present disclosure may still be referred to as “first” or “second” in the claims. In addition, terms that are referenced by a specific ordinal number (e.g., “first” in a particular claim) may be described elsewhere by a different ordinal number (e.g., “second” in the present disclosure or another claim).

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “GaAs”, “InAs”, “InP”, “SiC”, “SnAgCu”, and the like may refer to a material made of elements included in each of the terms and is not a chemical formula representing a stoichiometric relationship.

Hereinafter, various embodiments of the present disclosure are described with reference to the accompanying drawings.

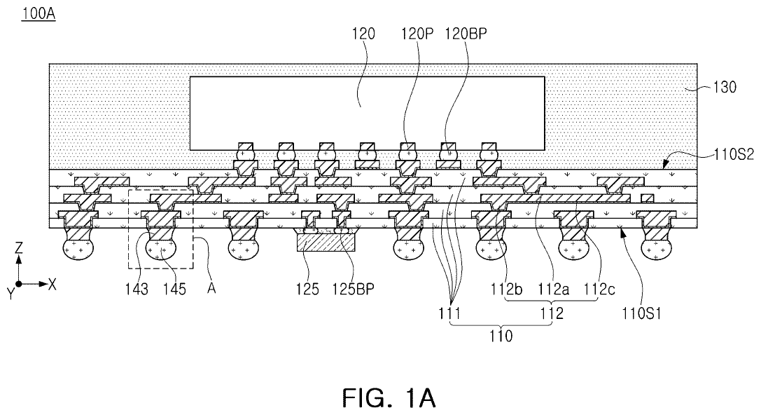

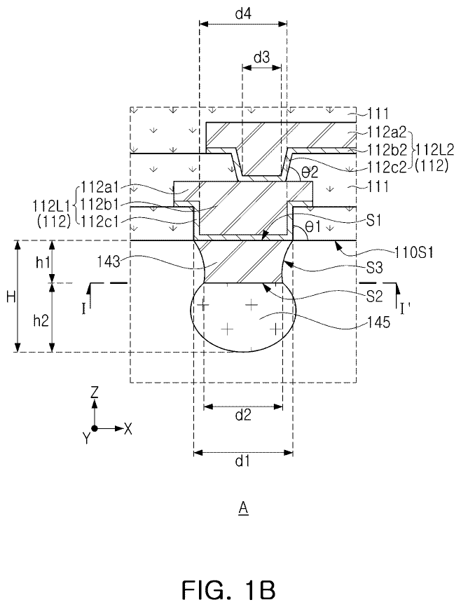

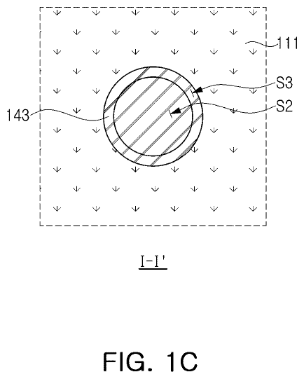

FIG. 1A is a cross-sectional view of a semiconductor package 100A, according to an example embodiment. FIG. 1B is a partially enlarged view of an area A of FIG. 1A, according to an example embodiment. FIG. 1C is a cross-sectional view taken along line I-I′ of FIG. 1B, according to an example embodiment.

Referring to FIGS. 1A, 1B, and 1C, the semiconductor package 100A may include a redistribution structure 110, a chip structure 120, and a pillar bump 143. According to an example embodiment, the semiconductor package 100A may further include a molding layer 130, through-vias 135, and/or solder bumps 145. The solder bumps 145 may include a low-melting-point metal, such as, but not limited to tin (Sn) or an alloy (e.g., a tin-silver-copper (SnAgCu) alloy) including tin (Sn).

The redistribution structure 110 may be and/or may include a support substrate on which the chip structure 120 is mounted, and may include an insulating layer 111 and redistribution conductors 112. The redistribution structure 110 may have a first surface 110S1 and a second surface 110S2 that may be opposite to each other. According to an example embodiment, a passive element 125 may be mounted on the first surface 110S1 and/or the second surface 110S2 of the redistribution structure 110. The passive element 125 may be electrically connected to the bottom pad 140P through a connection bump 125BP. The passive element 125 may improve signal integrity (SI) and/or power integrity (PI) characteristics of the semiconductor package, when compared to related semiconductor packages. The passive element 125 may include, for example, a capacitor, an inductor, beads, or the like. The passive element 125 may have a thickness smaller than the standoff height of the semiconductor package 100A. In an embodiment, the standoff height may refer to height H as shown in FIG. 1B.

The insulating layer 111 may surround respective at least portions of the redistribution conductors 112 and electrically isolate the redistribution conductors 112 that may be spaced apart from each other. The insulating layer 111 may include an insulating resin. The insulating resin may include a thermosetting resin such as, but not limited to, an epoxy resin, a thermoplastic resin such as, but not limited to, a polyimide, or a resin impregnated with an inorganic filler (e.g., a prepreg, an Ajinomoto build-up film (ABF), a flame retardant (FR)-4, or a bismaleimide-triazine (BT). In an example embodiment, the insulating layer 111 may include a photosensitive resin such as, but not limited to, a photo-imageable dielectric (PID). The insulating layer 111 may include a plurality of insulating layers that may be stacked in a vertical direction (Z-direction). Depending on the process, the boundaries between the plurality of insulating layers may be unclear.

The redistribution conductors 112 may redistribute the connection pads 120P of the chip structure 120. The redistribution conductors 112 may include, for example, copper (Cu), aluminum (Al), silver (Ag), tin (Sn), gold (Au), nickel (Ni), lead (Pb), titanium (Ti), or alloys thereof. In an example embodiment, the redistribution conductors 112 may include copper (Cu) or an alloy thereof. The redistribution conductors 112 may provide a transmission path for power signals, ground signals, data signals, or the like. The redistribution conductors 112 may be provided in more or fewer layers than those illustrated in the drawing.

The redistribution conductors 112 may include redistribution patterns 112a, redistribution vias 112b, and a seed layer 112c. The redistribution patterns 112a may be configured to extend in a horizontal direction (X- and Y-directions) within the insulating layer 111 to redistribute the connection pads 120P to the fan-out region. The redistribution conductors 112 may protrude on the second surface 110S2 of the insulating layer 111 and include pads connected to the chip structure 120. The redistribution vias 112b may be formed integrally with the redistribution patterns 112a. The redistribution vias 112b may be filled vias in which a metal material may be filled inside the via hole or conformal vias in which a metal material may extend along the inner wall of the via hole. The redistribution vias 112b may electrically connect the redistribution patterns 112a spaced apart in the vertical direction (Z-direction). At least some of the redistribution vias 112b may electrically connect the redistribution patterns 112a to corresponding pillar bumps 143. The seed layer 112c may be disposed along the lower surface of the redistribution pattern 112a and the side surface and lower surface of the redistribution via 112b. The seed layer 112c may cover respective at least portions of the lower surfaces and side surfaces of the redistribution vias 112b and the lower surfaces of the redistribution patterns 112a. The seed layer 112c may be formed in a single-layer or multi-layer thin film form. The seed layer 112c may include, for example, copper (Cu), aluminum (Al), silver (Ag), tin (Sn), gold (Au), nickel (Ni), lead (Pb), titanium (Ti), or alloys thereof. In an example embodiment, the seed layer 112c may include titanium (Ti), copper (Cu), or an alloy of at least one thereof.

As illustrated in FIG. 1B, the redistribution conductors 112 may include a first redistribution conductor 112L1 (also referred to as a lowermost redistribution conductor) on a pillar bump 143, and a second redistribution conductor 112L2 on the first redistribution conductor 112L1. The first redistribution conductor 112L1 may include a first redistribution pattern 112a1, and a first redistribution via 112b1 connecting the first redistribution pattern 112a1 to the pillar bump 143. The second redistribution conductor 112L2 may include a second redistribution pattern 112a2, and a second redistribution via 112b2 connecting the second redistribution pattern 112a2 to the first redistribution pattern 112a1. A first side surface of a first redistribution via 112b1 may have a first inclination angle θ1 with respect to a first surface 110S1, and a second side surface of a second redistribution via 112b2 may have a second inclination angle θ2 with respect to the first surface 110S1. The first inclination angle θ1 may be larger than the second inclination angle θ2. According to an example embodiment, to potentially improve connection reliability between a solder bump 145 and a pillar bump 143, a width d4 of the first redistribution via 112b1 connected to the pillar bump 143 may be larger than a width d3 of the second redistribution via 112b2. The first redistribution conductor 112L1 may further include a first seed layer 112c1, and the second redistribution conductor 112L2 may further include a second seed layer 112c2.

The chip structure 120 may be disposed on the second surface 110S2 of the redistribution structure 110 and may include connection pads 120P electrically connected to the redistribution conductors 112. The connection pads 120P may be electrically connected to the redistribution conductors 112 through connection bumps 120BP. The connection bumps 120BP may include a low-melting-point metal, such as, but not limited to, tin (Sn) or an alloy including tin (Sn). In some embodiments, the connection bumps 120BP may have a structure in which a metal pillar and a solder ball are combined. According to an example embodiment, an underfill layer may be disposed between the chip structure 120 and the redistribution structure 110 to surround the connection bumps 120BP. The underfill layer may have a molded underfill (MUF) structure integrated with the molding layer 130. However, embodiments of the present disclosure are not limited thereto. The underfill layer may also have a capillary underfill (CUF) structure.

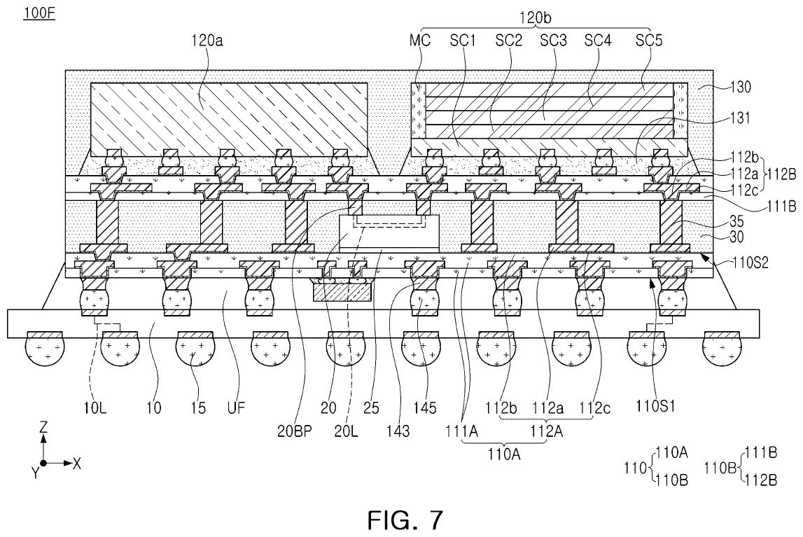

The chip structure 120 may include a semiconductor wafer and an integrated circuit (IC) made of a semiconductor element such as, but not limited to, silicon (Si), germanium (Ge), or a compound semiconductor such as, but not limited to, silicon carbide (SiC), gallium arsenide (GaAs), indium arsenide (InAs), or indium phosphide (InP). The chip structure 120 may be a bare semiconductor chip in which a separate bump or interconnection layer is not formed. However, embodiments of the present disclosure are not limited thereto. For example, the chip structure 120 may also be a packaged type semiconductor chip. According to an example embodiment, the chip structure 120 may be a package structure including a plurality of semiconductor chips, as described with reference to FIG. 7.

The chip structure 120 may include a logic circuit (or logic chip) such as, but not limited to, a central processing unit (CPU), a graphics processing unit (GPU), a field programmable gate array (FPGA), an application processor (AP), a digital signal processor (DSP), an encryption processor, a microprocessor, a microcontroller, an analog-to-digital converter (ADC), an application-specific IC (ASIC), or a memory circuit (or memory chip) including a volatile memory such as, but not limited to, a dynamic random access memory (DRAM), a static random access memory (SRAM), and a non-volatile memory such as, but not limited to, a phase change random access memory (PRAM), a magnetic random access memory (MRAM), a resistive random access memory (RRAM), a ferroelectric random access memory (FeRAM), or a flash memory.

The molding layer 130 may be disposed on the redistribution structure 110 and may cover at least a portion of the chip structure 120. The molding layer 130 may include, for example, a thermosetting resin such as, but not limited to, an epoxy resin, a thermoplastic resin such as, but not limited to, a polyimide, or a prepreg, ABF, FR-4, BT, epoxy molding compound (EMC), or the like.

The pillar bumps 143 may be disposed on the first surface 110S1 of the redistribution structure 110. The pillar bumps 143 may be electrically connected to the redistribution conductors 112. The pillar bumps 143 may electrically connect the chip structure 120 to an external device such as, but not limited to, a module substrate or a main board. The pillar bumps 143 may include a material similar to the redistribution conductors 112. The pillar bumps 143 may include, for example, at least one of copper (Cu), aluminum (Al), silver (Ag), tin (Sn), gold (Au), nickel (Ni), lead (Pb), titanium (Ti), or alloys thereof.

In an example embodiment, the pillar bumps 143 may be formed to have a uniform height by a simplified manufacturing process. The pillar bumps 143 may secure the standoff height of the semiconductor package 100A by spacing the solder bumps 145 and the redistribution structure 110 apart from each other by a considerable height, thereby minimizing the pitch between the solder bumps 145 and potentially improving reliability, when compared to related semiconductor packages. The height h1 of the pillar bump 143 may be about 30% or more of the height H from the lowest end of the solder bump 145 to the upper surface S1 of the pillar bump 143. The height h1 of the pillar bump 143 may be, for example, about 30 micrometers (μm) or more. However, embodiments of the present disclosure are not limited thereto. The height h2 of the solder bumps 145 may be similar to the height h1 of the pillar bump 143. The height h1 of the pillar bump 143 and the height h2 of the solder bumps 145 may be determined by considering the size and pitch of the solder bumps 145 and the required standoff height H.

The pillar bumps 143 may have an upper surface S1 connected to the redistribution conductors 112, a lower surface S2 connected to the solder bumps 145, and a side surface S3 intersecting the upper surface S1 and the lower surface S2. The upper surface S1 of the pillar bump 143 may be in contact with the bottom surface of the lowermost redistribution conductor 112L1. The bottom surface of the lowermost redistribution conductor 112L1 may be coplanar with the first surface 110S1 of the redistribution structure 110.

The pillar bump 143 may have a shape in which the side surface is tapered in a direction away from the first surface 110S1 of the redistribution structure 110. The lower surface S2 of the pillar bump 132 may have a second width d2 smaller than the first width d1 of the upper surface S1 of the pillar bump 143 in a first direction (e.g., X-direction). As a result, the size (e.g., width) of the solder bumps 145 may be formed smaller. The solder bumps 145 may be solder balls having a diameter corresponding to the width d2 of the lower surface S2 of the pillar bump 143.

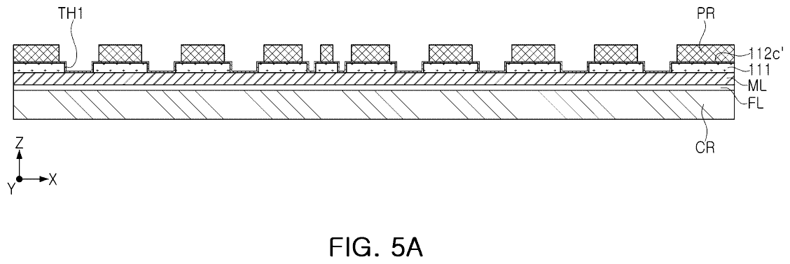

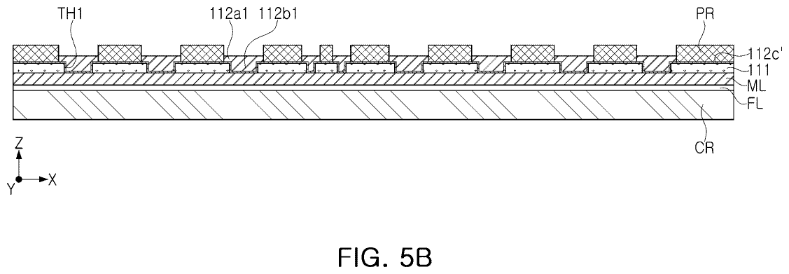

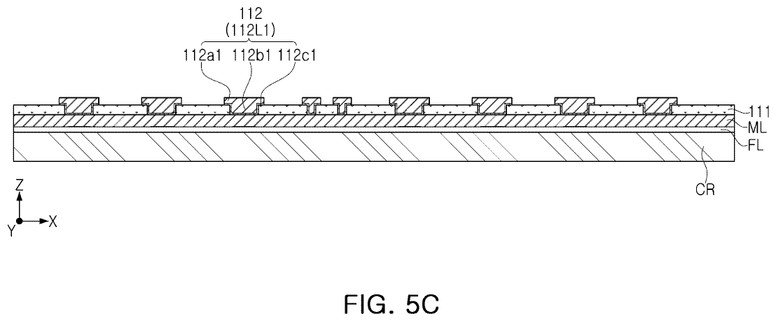

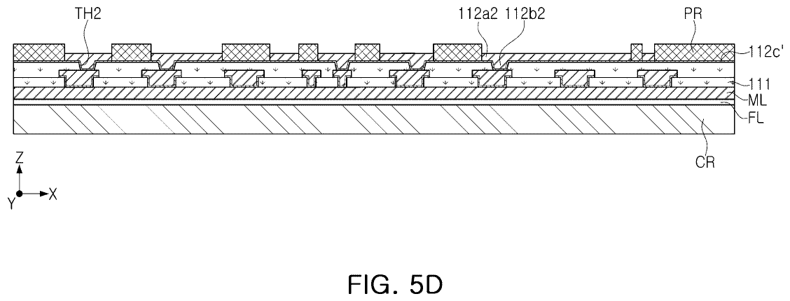

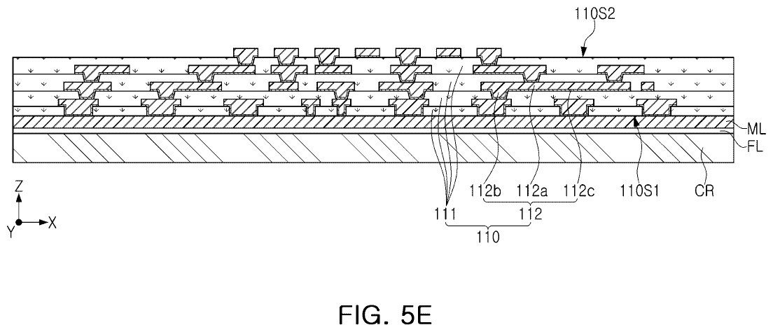

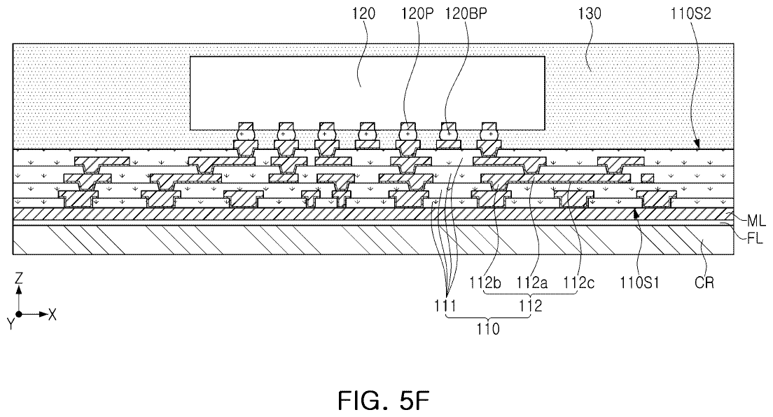

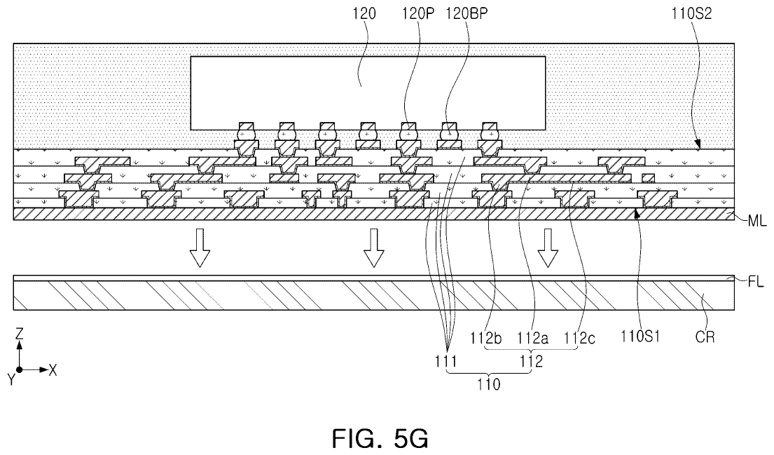

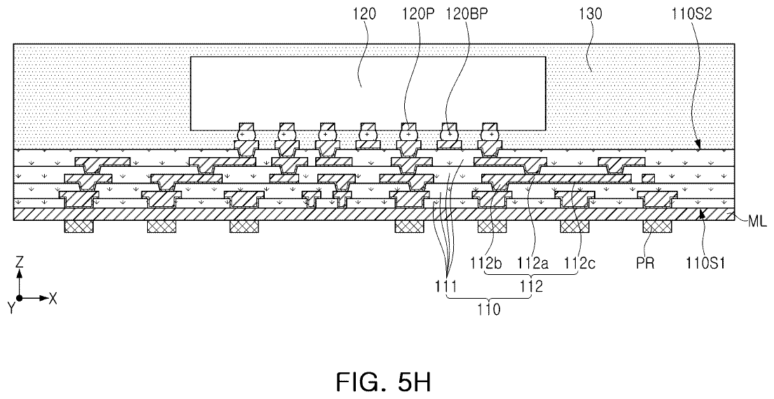

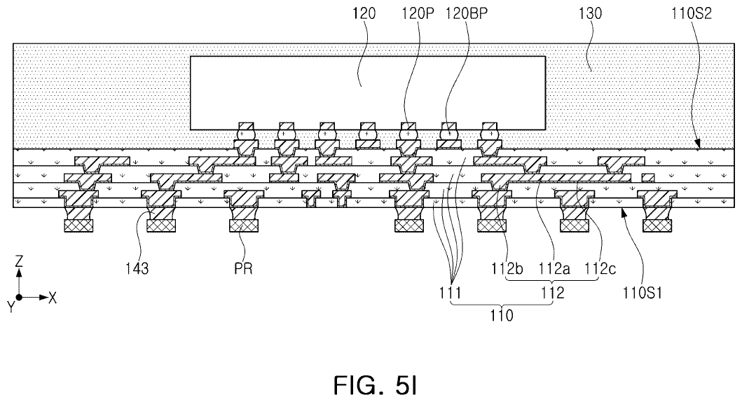

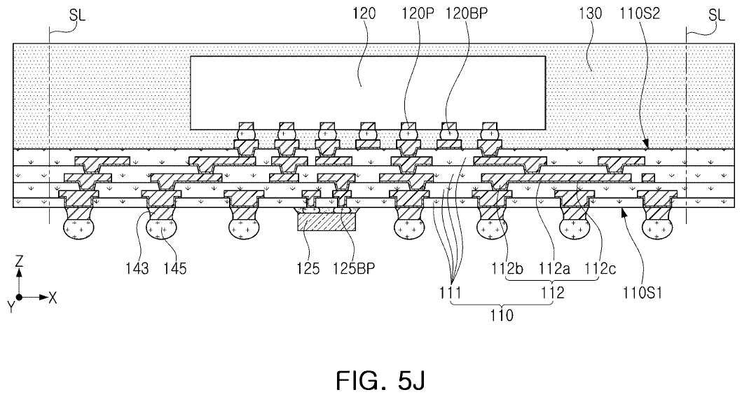

The side surface S3 of the pillar bump 143 may be a concave surface, curved in a direction parallel to the first surface 110S1 or in a horizontal direction (X- and Y-directions). For example, the side surface S3 of the pillar bump 143 may be a concave curved surface in the first direction (e.g., X-direction). The shape of the pillar bump 143 as described above may be implemented by a simplified manufacturing method, according to an example embodiment. The formation process of the pillar bump 143 is described with reference to FIGS. 5A, 5B, 5C, 5D, 5E, 5F, 5G, 5H, 5I, and 5J.

The pillar bump 143 may include a material having an etching selectivity with the seed layer 112c. Among the redistribution conductors 112, the lowermost redistribution conductor 112L1 may include a redistribution pattern 112a, a redistribution via 112b connecting the redistribution pattern 112a and the pillar bump 143, and a seed layer 112c extending between the redistribution via 112b and the pillar bump 143. The pillar bump 143 may include a first metal (e.g., copper (Cu) or the like), and the seed layer 112c may include a second metal (e.g., titanium (Ti), copper (Cu), or at least one thereof).

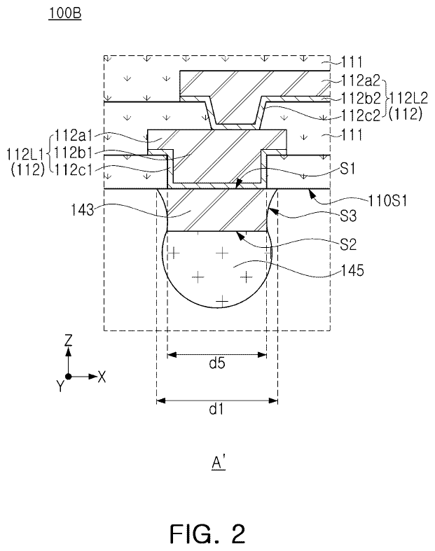

FIG. 2 is a partially enlarged view of a semiconductor package 100B, according to an example embodiment. Referring to FIG. 2, an area A′ of the semiconductor package 100B is illustrated, which similar to the area A of the semiconductor package 100A illustrated in FIG. 1B.

The semiconductor package 100B depicted in FIG. 2 may include and/or may be similar in many respects to the semiconductor package 100A described above with reference to FIGS. 1A, 1B, and 1C, and may include additional features not mentioned above. Consequently, repeated descriptions of the semiconductor package 100B described above with reference to FIGS. 1A, 1B, and 1C may be omitted for the sake of brevity.

For example, in the semiconductor package 100B, the width of the pillar bump 143 may be larger than the width of the lowermost redistribution via 112b1. The upper surface S1 of the pillar bump 143 may be in contact with the bottom surface of the lowermost redistribution conductor 112L1. The width d5 of the bottom surface of the lowermost redistribution conductor 112L1 may be smaller than the width d1 of the upper surface S1 of the pillar bump 143. In an embodiment, the upper surface S1 of the pillar bump 143 may be in contact with the lowermost redistribution conductor 112L1 and the insulating layer 111 surrounding the lowermost redistribution conductor 112L1.

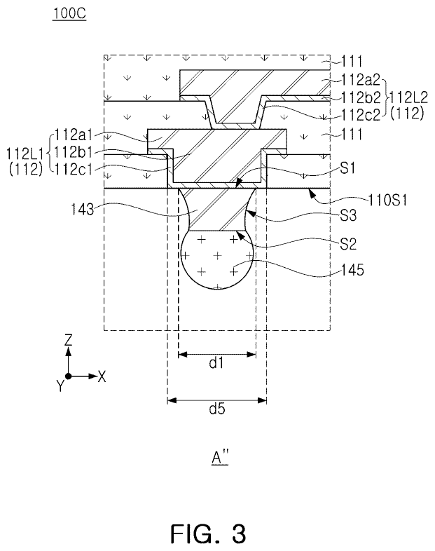

FIG. 3 is a partially enlarged view of a semiconductor package 100C, according to an example embodiment. Referring to FIG. 3, an area A″ of the semiconductor package 100C is illustrated, which similar to the area A of the semiconductor package 100A illustrated in FIG. 1B and the area A′ of the semiconductor package 100B illustrated in FIG. 2.

The semiconductor package 100C depicted in FIG. 3 may include and/or may be similar in many respects to the semiconductor packages 100A and 100B described above with reference to FIGS. 1A, 1B, 1C, and 2, and may include additional features not mentioned above. Consequently, repeated descriptions of the semiconductor package 100C described above with reference to FIGS. 1A, 1B, 1C, and 2 may be omitted for the sake of brevity.

For example, in the semiconductor package 100C, the width of the pillar bump 143 may be smaller than the width of the lowermost redistribution via 112b1. The upper surface S1 of the pillar bump 143 may be in contact with the bottom surface of the lowermost redistribution conductor 112L1. The width d5 of the bottom surface of the lowermost redistribution conductor 112L1 may be larger than the width d1 of the upper surface S1 of the pillar bump 143. In an embodiment, the seed layer 112c1 of the lowermost redistribution conductor 112L1 may be exposed at least partially from the pillar bump 143. The seed layer 112c1 may be exposed around the pillar bump 143 without being etched in the formation process of the pillar bump 143.

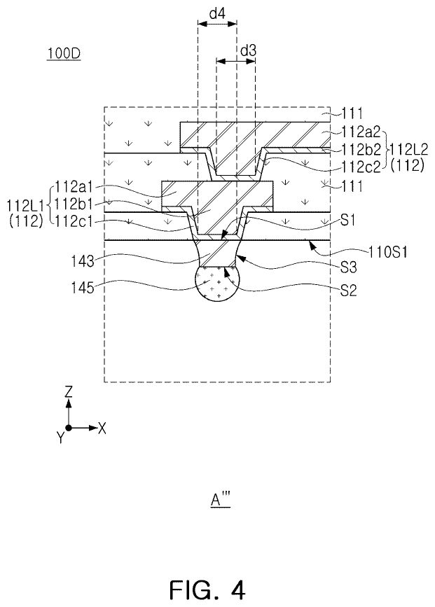

FIG. 4 is a partially enlarged view of a semiconductor package 100D, according to an example embodiment. Referring to FIG. 4, an area A″′ of the semiconductor package 100D is illustrated, which similar to the area A of the semiconductor package 100A illustrated in FIG. 1B, the area A′ of the semiconductor package 100B illustrated in FIG. 2, and the area A″ of the semiconductor package 100C illustrated in FIG. 3.

The semiconductor package 100D depicted in FIG. 4 may include and/or may be similar in many respects to the semiconductor packages 100A, 100B, and 100C described above with reference to FIGS. 1A, 1B, 1C, 2, and 3, and may include additional features not mentioned above. Consequently, repeated descriptions of the semiconductor package 100D described above with reference to FIGS. 1A, 1B, 1C, 2, and 3 may be omitted for the sake of brevity.

In the semiconductor package 100D, the redistribution vias 112b1, 112b2 may have a shape in which side surfaces may be tapered in the same direction. For example, the first redistribution via 112b1 and the second redistribution via 112b2 may have a shape that is tapered toward the first surface 110S1. The width d4 of the first redistribution via 112b1 in the first direction may be greater than or equal to the width d3 of the second redistribution via 112b2 in the first direction. In some embodiments, the first redistribution via 112b1 may have a tapered shape toward the first surface 110S1 and a width d4 greater than the width d3 of the second redistribution via 112b2.

FIGS. 5A, 5B, 5C, 5D, 5E, 5F, 5G, 5H, 5I, and 5J are diagrams illustrating a manufacturing process of a semiconductor package, according to an example embodiment.

Referring to FIG. 5A, a carrier substrate CR on which a thin film layer FL and a metal layer ML are sequentially stacked may be prepared. The carrier substrate CR may be and/or may include a temporary support including a curable resin layer, or the like. The carrier substrate CR may have a quadrangular and/or rectangular panel shape. However, embodiments of the present disclosure are not limited thereto. The thin film layer FL may be and/or may include a metal foil conformally formed on at least one surface of the carrier substrate CR. For example, the carrier substrate CR may be and/or may include a copper clad laminate (CCL), an unclad CCL, or the like on which a copper thin film layer FL may be formed. A metal layer ML may be formed on the thin film layer FL to a predetermined thickness. The metal layer ML may include a material similar to the thin film layer FL, for example, copper (Cu). The metal layer ML may be formed to a thickness corresponding to the height of the pillar bump 143 described above. In addition, the metal layer ML may be formed to have a substantially uniform thickness. For example, according to an example embodiment, since the pillar bump 143 is formed by etching the metal layer ML without a separate plating process, the manufacturing process of the semiconductor package may be simplified and the height deviation of the pillar bump 143 may be minimized, when compared to a related semiconductor package.

An insulating layer 111 and a plating seed layer 112c′ may be formed on a metal layer ML. The insulating layer 111 may be formed using a photosensitive resin such as, but not limited to, PID. The insulating layer 111 may have first via holes TH1 formed by a photolithography process. The plating seed layer 112c′ may be conformally formed along a surface of the insulating layer 111 by a deposition process. The plating seed layer 112c′ may be and/or may include a double layer including, but not limited to, titanium (Ti), copper (Cu), or the like. A photosensitive material layer PR patterned by a photolithography process may be formed on the plating seed layer 112c′.

Referring to FIG. 5B, a first redistribution pattern 112a1 and a first redistribution via 112b1 may be formed. The first redistribution pattern 112a1 and the first redistribution via 112b1 may be formed by an electroplating process using a plating seed layer 112c′. The first redistribution pattern 112a1 and the first redistribution via 112b1 may include copper (Cu) or an alloy thereof. Thereafter, the photosensitive material layer PR may be removed by an ashing process.

Referring to FIG. 5C, a first redistribution conductor 112L1 including a first seed layer 112c1 may be formed. The first seed layer 112c1 may be formed by etching the plating seed layer 112c′ exposed after the photosensitive material layer PR is removed. Between the metal layer ML and the redistribution conductor 112, a first seed layer 112c1 (e.g., titanium (Ti)) having an etching selectivity with respect to the metal layer ML (e.g., copper (Cu)) may remain.

Referring to FIG. 5D, the above-described process (described with reference to FIGS. 5A, 5B, and 5C) may be similarly repeated to form an insulating layer 111, a second redistribution pattern 112a2, and a second redistribution via 112b2. The insulating layer 111 may be formed to have second via holes TH2. The second redistribution pattern 112a2 and the second redistribution via 112b2 may be formed by an electroplating process using a plating seed layer 112c′. Thereafter, the photosensitive material layer PR may be removed, and the second seed layer 112c2 may be formed.

Referring to FIG. 5E, a redistribution structure 110 including an insulating layer 111 and redistribution conductors 112 may be formed. The redistribution structure 110 may include a first surface 110S1 contacting a metal layer ML and a second surface 110S2 opposite to the first surface 110S1.

Referring to FIG. 5F, a chip structure 120 and a molding layer 130 may be formed on the redistribution structure 110. The chip structure 120 may be mounted in a flip-chip manner. The chip structure 120 may be connected to the redistribution conductors 112 through a connection bump 120BP. The molding layer 130 may be formed by applying and curing a molding material such as, but not limited to, EMC.

Referring to FIG. 5G, the carrier substrate CR may be detached. The carrier substrate CR may be detached together with the thin film layer FL. The thin film layer FL may be detached together with the carrier substrate CR from the metal layer ML having relatively low bonding strength. The metal layer ML may remain on the first surface 110S1 of the redistribution structure 110. The metal layer ML may be transferred from the carrier substrate CR to the first surface 110S1 of the redistribution structure 110.

Referring to FIGS. 5H and 5I, pillar bumps 143 may be formed. The pillar bumps 143 may be formed by partially removing the metal layer ML. The metal layer ML may be partially etched using the patterned photosensitive material layer PR. The pillar bumps 143 may be formed by a wet etching process of the metal layer ML. The photosensitive material layer PR may be removed by an ashing process. Each of the pillar bumps 143 may have an upper surface contacting the redistribution conductors 112, a lower surface contacting the photosensitive material layer PR, and a side surface intersecting the upper surface and the lower surface. As described with reference to FIG. 1B, the lower surface of the pillar bump 143 may have a width smaller than the width of the upper surface of the pillar bump 143 in the horizontal direction, and the side surface of the pillar bump 143 may be a concave curved surface in the horizontal direction. In this manner, the pillar bumps 143 having a uniform height may be formed by etching the metal layer ML detached from the carrier substrate CR without a separate plating process.

Referring to FIG. 5J, solder bumps 145 may be formed on pillar bumps 143. The solder bumps 145 may be attached on the lower surfaces of the pillar bumps 143. According to an example embodiment, a passive element 125 may be mounted on the first surface 110S1 of the redistribution structure 110. Thereafter, a cutting process may be performed along a scribe lane SL to separate individual semiconductor packages.

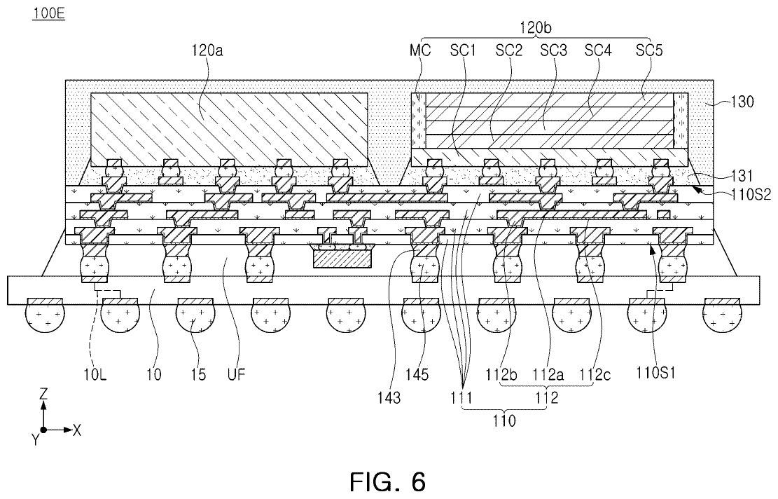

FIG. 6 is a cross-sectional view of a semiconductor package 100E, according to an example embodiment.

Referring to FIG. 6, the semiconductor package 100E may include and/or may be similar in many respects to the semiconductor packages 100A, 100B, 100C, and 100D described above with reference to FIGS. 1A, 1B, 1C, 2, 3, 4, 5A, 5B, 5C, 5D, 5E, 5F, 5G, 5H, 5I, and 5J, and may include additional features not mentioned above. Consequently, repeated descriptions of the semiconductor package 100E described above with reference to FIGS. 1A, 1B, 1C, 2, 3, 4, 5A, 5B, 5C, 5D, 5E, 5F, 5G, 5H, 5I, and 5J may be omitted for the sake of brevity.

As shown in FIG. 6, the semiconductor package 100E may include a substrate 10 on which a redistribution structure 110 is mounted, and a plurality of chip structures (e.g., a first chip structure 120a and a second chip structure 120b) electrically connected to each other through redistribution conductors 112. In an example embodiment, the redistribution structure 110 may be understood and/or may function as an interposer and/or an interposer substrate.

The substrate 10 may be and/or may include a semiconductor package substrate including, but not limited to, a printed circuit board (PCB), a ceramic substrate, a glass substrate, a tape interconnection substrate, or the like. The substrate 10 may include a wiring circuit 10L that may electrically connect solder bumps 145 and connection bumps 15. The wiring circuit 10L may electrically connect the plurality of chip structures 120a and 120b to the connection bumps 15. The wiring circuit 10L may include at least one metal such as, but not limited to, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or an alloy composed of two or more metals. An underfill UF surrounding the solder bumps 145 may be formed on the substrate 10. The underfill UF may include a thermosetting resin such as, but not limited to, an epoxy resin, and may be formed to seal the solder bumps 145 and the pillar bumps 143 by a capillary underfill (CUF) method.

The plurality of chip structures 120a and 120b may be disposed side by side on a redistribution structure 110. The plurality of chip structures 120a and 120b may be fixed on the redistribution structure 110 by an underfill layer 131. The underfill layer 131 may have a CUF structure, but may also have a MUF structure integrated with a molding layer 130, according to an example embodiment. The plurality of chip structures 120a and 120b may include different types of semiconductor chips. For example, the first chip structure 120a may include a logic chip such as, but not limited to, a CPU, a GPU, an FPGA, a DSP, an encryption processor, a microprocessor, a microcontroller, an ADC, an ASIC, or the like, and the second chip structure 120b may include a memory chip such as, but not limited to, a DRAM, an SRAM, a PRAM, an RRAM, an FeRAM, an MRAM, a flash memory, or the like. According to an example embodiment, the second chip structure 120b may be provided as a high-performance memory device such as, but not limited to, a high bandwidth memory (HBM), a hybrid memory cube (HMC), or the like.

The second chip structure 120b may include a plurality of semiconductor chips (e.g., a first semiconductor chip SC1, a second semiconductor chip SC2, a third semiconductor chip SC3, a fourth semiconductor chip SC4, and a fifth semiconductor chip SC5) and a sealing layer MC. The plurality of semiconductor chips SC1 to SC5 may be provided in more or less numbers than those illustrated in the drawing. The plurality of semiconductor chips SC1 to SC5 may be stacked in a vertical direction (Z-direction) by a thermocompression bonding method or a hybrid bonding method. The plurality of semiconductor chips SC1 to SC5 may be interconnected by through silicon vias (TSVs). The plurality of semiconductor chips SC1 to SC5 may include a buffer chip (e.g., the first semiconductor chip SC1) and a plurality of memory chips (e.g., the second to fifth semiconductor chips SC2 to SC5). The sealing layer MC may include an insulating material such as, but not limited to, an EMC, for example.

FIG. 7 is a cross-sectional view of a semiconductor package 100F, according to an example embodiment.

Referring to FIG. 7, the semiconductor package 100F may include and/or may be similar in many respects to the semiconductor packages 100A, 100B, 100C, 100D, and 100E described above with reference to FIGS. 1A, 1B, 1C, 2, 3, 4, 5A, 5B, 5C, 5D, 5E, 5F, 5G, 5H, 5I, 5J, and 6, and may include additional features not mentioned above. Consequently, repeated descriptions of the semiconductor package 100F described above with reference to FIGS. 1A, 1B, 1C, 2, 3, 4, 5A, 5B, 5C, 5D, 5E, 5F, 5G, 5H, 5I, 5J, and 6 may be omitted for the sake of brevity.

As shown in FIG. 7, in the semiconductor package 100F, the redistribution structure 110 may include a lower structure 110A, an upper structure 110B, and an interconnection chip 20. For example, the redistribution structure 110 may include a lower structure 110A, an interconnection chip 20, a mold 30, through-vias 35, and an upper structure 110B.

The lower structure 110A may include a lower insulating layer 111A and lower redistribution conductors 112A. The lower insulating layer 111A may be formed using a photosensitive resin. The lower insulating layer 111A may include at least one of a polyimide (PI)-based photosensitive polymer, a polybenzoxazole (PBO)-based photosensitive polymer, a polyhydroxystyrene (PHS)-based photosensitive polymer, a novolak-based photosensitive polymer, and a benzocyclobutene (BCB)-based photosensitive polymer. For example, the lower insulating layer 111A may include a PID. The lower redistribution conductors 112A may be disposed on or within the lower insulating layer 111A and may be electrically connected to the through-vias 35. The lower redistribution conductors 112A may include, for example, copper (Cu), aluminum (Al), silver (Ag), tin (Sn), gold (Au), nickel (Ni), lead (Pb), titanium (Ti), or alloys thereof.

The interconnection chip 20 may be disposed on the lower structure 110A. An adhesive layer 25 may be disposed between the interconnection chip 20 and the lower structure 110A. The interconnection chip 20 may include an interconnection circuit 20L for electrically connecting the first chip structure 120a and the second chip structure 120b. The interconnection chip 20 may be a semiconductor chip in which the interconnection circuit 20L is formed on a semiconductor substrate. However, embodiments of the present disclosure are not limited thereto. The interconnection circuit 20L may be electrically connected to the upper redistribution conductors 112B through the connection bump 20BP.

The mold 30 may be disposed between the lower structure 110A and the upper structure 110B. The mold 30 may be formed to seal the interconnection chip 20 and the through-vias 35. The mold 30 may include, for example, a thermosetting resin such as, but not limited to, an epoxy resin, a thermoplastic resin such as, but not limited to, a polyimide, or a prepreg, ABF, FR-4, BT, EMC, or the like, impregnated with an inorganic filler in these resins.

The through-vias 35 may be disposed around the interconnection chip 20 and may electrically connect the lower redistribution conductor 112A and the upper redistribution conductor 112B. The through-vias 35 may have a post shape that may extend in the vertical direction (Z) corresponding to the thickness of the interconnection chip 20. One side (e.g., the upper surface) of the through-vias 35 may be coplanar with one side (e.g., the upper surface) of the mold 30 by a planarization process. The through-vias 35 may include copper (Cu), aluminum (Al), silver (Ag), tin (Sn), gold (Au), nickel (Ni), lead (Pb), titanium (Ti), or alloys thereof.

The upper structure 110B may include an upper insulating layer 111B and upper redistribution conductors 112B. The upper insulating layer 111B and upper redistribution conductors 112B may have substantially similar characteristics to the lower insulating layer 111A and the lower redistribution conductors 112A described above, and therefore, a repeated description may be omitted for the sake of brevity. The upper redistribution conductors 112B may be connected to the interconnection circuit 20L through the redistribution via 112b. The plurality of chip structures 120a and 120b may be electrically connected to the interconnection chip 20 through the upper redistribution conductors 112B.

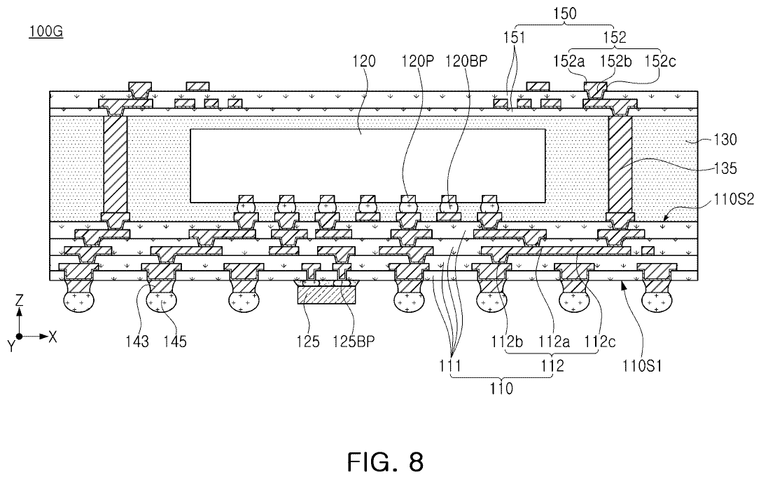

FIG. 8 is a cross-sectional view of a semiconductor package 100G, according to an example embodiment.

Referring to FIG. 8, the semiconductor package 100G may include and/or may be similar in many respects to the semiconductor packages 100A, 100B, 100C, 100D, 100E, and 100F described above with reference to FIGS. 1A, 1B, 1C, 2, 3, 4, 5A, 5B, 5C, 5D, 5E, 5F, 5G, 5H, 5I, 5J, 6, and 7, and may include additional features not mentioned above. Consequently, repeated descriptions of the semiconductor package 100G described above with reference to FIGS. 1A, 1B, 1C, 2, 3, 4, 5A, 5B, 5C, 5D, 5E, 5F, 5G, 5H, 5I, 5J, 6, and 7 may be omitted for the sake of brevity.

As shown in FIG. 8, the semiconductor package 100G may further include through-vias 135 and an upper redistribution structure 150.

The through-vias 135 may be disposed around the chip structure 120. The through-vias 135 may electrically connect the redistribution conductors 112 and the upper redistribution conductors 152. The through-vias 135 may include, for example, copper (Cu), aluminum (Al), silver (Ag), tin (Sn), gold (Au), nickel (Ni), lead (Pb), titanium (Ti), or alloys thereof. The through-vias 135 may have a cylindrical shape extending in the vertical direction (Z-direction). However, embodiments of the present disclosure are not limited thereto.

The upper redistribution structure 150 may be disposed on the molding layer 130 and may include an insulating layer 151 and upper redistribution conductors 152. The upper redistribution conductors 152 may include redistribution patterns 152a, redistribution vias 152b, and a seed layer 152c. The redistribution vias 152b may be formed integrally with the redistribution patterns 152a. At least some of the redistribution vias 152b may electrically connect the redistribution patterns 152a to the corresponding through-vias 135. The seed layer 152c may be disposed along the lower surface of the redistribution pattern 152a and the side surface and lower surface of the redistribution via 152b.

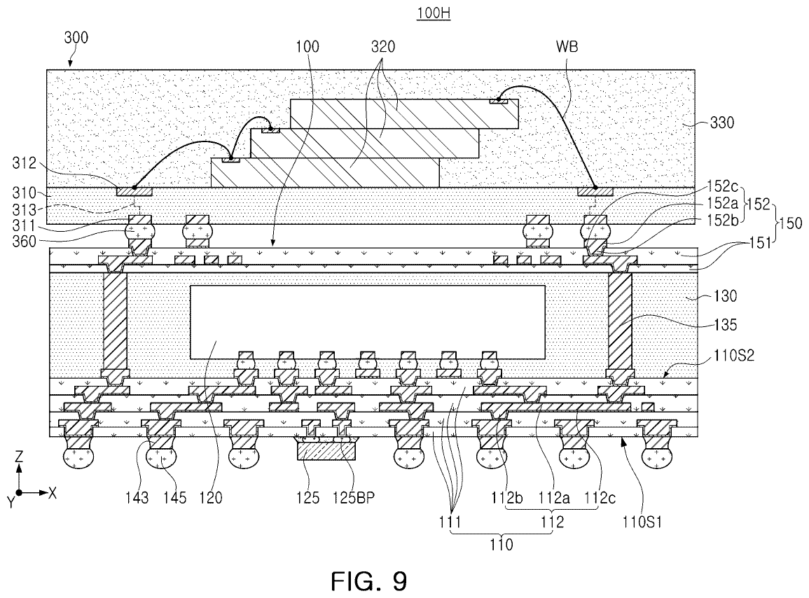

FIG. 9 is a cross-sectional view of a semiconductor package 100H, according to an example embodiment.

Referring to FIG. 9, the semiconductor package 100H may include and/or may be similar in many respects to the semiconductor packages 100A, 100B, 100C, 100D, 100E, 100F, and 100G described above with reference to FIGS. 1A, 1B, 1C, 2, 3, 4, 5A, 5B, 5C, 5D, 5E, 5F, 5G, 5H, 5I, 5J, 6, 7, and 8, and may include additional features not mentioned above. Consequently, repeated descriptions of the semiconductor package 100H described above with reference to FIGS. 1A, 1B, 1C, 2, 3, 4, 5A, 5B, 5C, 5D, 5E, 5F, 5G, 5H, 5I, 5J, 6, 7, and 8 may be omitted for the sake of brevity.

As shown in FIG. 9, the semiconductor package 100H may further include an upper package 300.

The upper package 300 may be disposed on the upper redistribution structure 150. The upper package 300 may include an interconnection substrate 310, a semiconductor chip 320, and an encapsulant 330. The interconnection substrate 310 may include a lower pad 311 and an upper pad 312. In addition, the interconnection substrate 310 may include a wiring circuit 313 that may electrically connect the lower pad 311 and the upper pad 312. The interconnection substrate 310 may be and/or may include a semiconductor package substrate including a PCB, a ceramic substrate, a glass substrate, a tape interconnection substrate, or the like. For example, the interconnection substrate 310 may be a double-sided PCB or a multi-layer PCB.

The semiconductor chip 320 may be mounted on the interconnection substrate 310 by wire bonding and/or flip chip bonding. For example, a plurality of semiconductor chips 320 may be stacked vertically on the interconnection substrate 310 and may be electrically connected to the upper pad 312 of the interconnection substrate 310 by bonding wires WB. In an example, the semiconductor chip 320 of the upper package 300 may include a memory chip, and the chip structure 120 mounted on the redistribution structure 110 may include an AP chip. The semiconductor chip 320 may be electrically connected to the chip structure 120 through a conductive bump 360, an upper redistribution conductor 152, and a through-via 135. The encapsulant 330 may include a material substantially similar to and/or the same as a molding layer 130 of the lower package 100.

As set forth above, according to example embodiments, a semiconductor package with improved reliability, when compared to related semiconductor packages, may be provided by introducing a pillar bump formed using a carrier substrate.

While example embodiments have been illustrated and described above, it is to be apparent to those skilled in the art that modifications and variations may be made without departing from the scope of the present disclosure as defined by the appended claims.

What is claimed is:

1. A semiconductor package, comprising:
a redistribution structure comprising a first surface and a second surface opposite to the first surface, and comprising an insulating layer and redistribution conductors on the insulating layer;
a pillar bump on the first surface and coupled with the redistribution conductors;
a solder bump on the pillar bump;
a first chip structure and a second chip structure on the second surface and coupled with each other through the redistribution conductors; and
a molding layer at partially covering the first chip structure and the second chip structure,
wherein the pillar bump comprises an upper surface coupled with the redistribution conductors, a lower surface coupled with the solder bump, and a side surface intersecting the upper surface and the lower surface,
wherein a second width of the lower surface of the pillar bump is smaller than a first width of the upper surface of the pillar bump, in a first direction, and
wherein the side surface of the pillar bump comprises a concave surface in the first direction.

2. The semiconductor package of claim 1, wherein a lowermost redistribution conductor from among the redistribution conductors comprises a bottom surface contacting the upper surface of the pillar bump, and
wherein the bottom surface of the lowermost redistribution conductor is coplanar with the first surface of the redistribution structure.

3. The semiconductor package of claim 1, wherein a first height of the pillar bump is 30% or more of a second height from a lowest end of the solder bump to the upper surface of the pillar bump.

4. The semiconductor package of claim 3, wherein the first height of the pillar bump is 30 micrometers (μm) or more.

5. The semiconductor package of claim 1, wherein a lowermost redistribution conductor from among the redistribution conductors comprises:
a redistribution pattern;
a redistribution via coupling the redistribution pattern with the pillar bump; and
a seed layer between the redistribution via and the pillar bump.

6. The semiconductor package of claim 5, wherein the pillar bump comprises a first metal, and
wherein the seed layer comprises a second metal.

7. The semiconductor package of claim 6, wherein the first metal comprises at least one of copper (Cu) or an alloy thereof, and
wherein the second metal comprises at least one of titanium (Ti), copper (Cu), or an alloy thereof.

8. The semiconductor package of claim 1, wherein a lowermost redistribution conductor from among the redistribution conductors comprises a bottom surface in contact with the upper surface of the pillar bump, and
wherein the first width of the upper surface of the pillar bump is larger than a third width of the bottom surface of the lowermost redistribution conductor.

9. The semiconductor package of claim 1, wherein a lowermost redistribution conductor from among the redistribution conductors comprises a bottom surface contacting the upper surface of the pillar bump, and
wherein the first width of the upper surface of the pillar bump is smaller than a third width of the bottom surface of the lowermost redistribution conductor.

10. The semiconductor package of claim 1, wherein the redistribution conductors comprise a first redistribution conductor on the pillar bump and a second redistribution conductor on the first redistribution conductor,
wherein the first redistribution conductor comprises a first redistribution pattern and a first redistribution via coupling the first redistribution pattern with the pillar bump, and
wherein the second redistribution conductor comprises a second redistribution pattern and a second redistribution via coupling the second redistribution pattern with the first redistribution pattern.

11. The semiconductor package of claim 10, wherein the first redistribution via comprises a first side surface forming a first inclination angle with respect to the first surface,
wherein the second redistribution via has a second side surface forming a second inclination angle with respect to the first surface, and
wherein the first inclination angle is greater than the second inclination angle.

12. The semiconductor package of claim 10, wherein a third width of the first redistribution via in the first direction is greater than or equal to a fourth width of the second redistribution via in the first direction.

13. The semiconductor package of claim 10, wherein the first redistribution via and the second redistribution via comprise a shape tapered toward the first surface.

14. The semiconductor package of claim 1, wherein the first chip structure comprises a logic chip, and
wherein the second chip structure comprises a memory chip.

15. The semiconductor package of claim 1, further comprising:
a substrate comprising a wiring circuit; and
connection bumps below the substrate,
wherein the redistribution structure is on the substrate, and
wherein the first chip structure and the second chip structure are coupled with the connection bumps through the wiring circuit.

16. A semiconductor package, comprising:
a redistribution structure comprising a first surface and a second surface opposite to the first surface, and comprising redistribution conductors;
a pillar bump on the first surface and coupled with the redistribution conductors;
a chip structure on the second surface and coupled with the redistribution conductors; and
a molding layer at partially covering the chip structure,
wherein a lowermost redistribution conductor from among the redistribution conductors comprises a redistribution pattern, a redistribution via coupling the redistribution pattern with the pillar bump, and a seed layer extending between the redistribution via and the pillar bump,
wherein the pillar bump comprises a first metal, and
wherein the seed layer comprises a second metal having an etching selectivity with respect to the first metal.

17. The semiconductor package of claim 16, wherein the first metal comprises at least one of copper (Cu) or an alloy thereof, and
wherein the second metal comprises at least one of titanium (Ti), copper (Cu), or an alloy thereof.

18. The semiconductor package of claim 16, wherein the pillar bump comprises a shape in which a side surface is tapered in a first direction away from the first surface.

19. The semiconductor package of claim 18, wherein the side surface of the pillar bump comprises a concave surface in a second direction parallel to the first surface.

20. A semiconductor package, comprising:
a redistribution structure comprising a first surface and a second surface opposite to the first surface, and comprising an insulating layer and redistribution conductors on the insulating layer;
a pillar bump on the first surface and coupled with the redistribution conductors;
a solder bump on the pillar bump; and
at least one chip structure on the second surface and coupled with the redistribution conductors,
wherein the pillar bump comprises a side surface exposed from the insulating layer, and
wherein the side surface of the pillar bump comprises a concave surface.
